(19) United States
(12) Patent Application Publication
(10) Pub. No.: US 2010/0096645 A1
(43) Pub. Date: Apr. 22, 2010

(54) DISPLAY DEVICE AND MANUFACTURING METHOD THEREOF

(75) Inventors: Daisuke Sonoda, Chiba (JP); Toshio Miyazawa, Chiba (JP); Takuo Kaitoh, Mobara (JP); Yasukazu Kimura, Chiba (JP); Takeshi Kuriyagawa, Mobara (JP); Takeshi Noda, Mobara (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi Displays, Ltd.

(21) Appl. No.: 12/579,428

(22) Filed: Oct. 15, 2009

(30) Foreign Application Priority Data
Oct. 17, 2008 (JP) 2008-268989

(51) Int. Cl. H01L 33/00

(52) U.S. Cl. 257/88; 438/34; 257/59; 257/72; 438/597; 257/E33.066; 257/E33.005

(57) ABSTRACT

A manufacturing method of a display device and a display device which can reduce the number of times that an insulation substrate is put into a CVD device and is taken out from the CVD device are provided. The manufacturing method of a display device includes the steps of forming a conductive layer including first electrode films and second electrode films, a first insulation layer, semiconductor films, a second insulation layer and a protective layer on an insulation substrate; forming first resist films having a predetermined thickness which are arranged in first regions above the semiconductor films, opening portions which are arranged in second regions above the second electrode films and second resist films having a large thickness which are arranged in regions other than the first regions and the second regions on the protective layer; etching portions below the second regions, removing the first resist films by ashing; forming first holes which reach the semiconductor films below the first regions and second holes which reach the second electrode films below the second regions; removing the second resist films, and forming lines which are connected to the semiconductor films and lines which are connected to the second electrode films.

The present application claims priority from Japanese applications JP 2008-268989 filed on Oct. 17, 2008, the content of which is hereby incorporated by reference into this application.

### BACKGROUND OF THE INVENTION

1. Field of the Invention

The present invention relates to a display device and a manufacturing method of the display device.

2. Description of the Related Art

For example, in a display device as represented by a liquid crystal display device, an array substrate which constitutes a part of the display device includes thin film transistors, line-use electrodes CM and contact holes which connect the line-use electrodes CM with lines in general.

FIG. 15 shows a cross section of a thin film transistor and a contact hole formed on an array substrate of a conventional liquid crystal display device. The conventional array substrates includes: a glass substrate SUB formed of an insulating substrate; a first conductive layer which is formed on the glass substrate SUB and from which gate electrodes GM and line-use electrodes CM are formed; a first insulation layer GI which is formed on the first conductive layer; a semiconductor layer which is formed on the first insulation layer and from which semiconductor films PS are formed over the first electrode film; a second insulation layer SI which is formed on the semiconductor layers; a plurality of contact holes CH1, CH2 which penetrate the second insulation layer and reach the semiconductor films; contact holes CH3 which penetrate the second insulation layer and the first insulation layer and reach the second electrode films; drain electrodes DT and source electrodes ST which are lines electrically connected to the semiconductor films PS via the contact holes CH1, CH2; lines CE which are electrically connected to the second electrode films via the contact holes CH3; and a protective layer PI which is formed over these lines. The gate electrode GM, the semiconductor film PS, the drain electrode DT and the source electrode ST constitute the thin film transistor.

FIG. 16 to FIG. 21 show a method of manufacturing a conventional display device, and more particularly an array substrate of the display device. The array substrate of the conventional display device is manufactured by a following manufacturing method. Firstly, the formation and patterning of the conductive layer including the gate electrodes GM and the line-use electrodes CM on a glass substrate SUB, the formation of the first insulation layer GI on the glass substrate SUB, and the formation and patterning of the semiconductor films PS on the glass substrate SUB (see FIG. 16) are performed thus forming the respective layers. A known photolithography technique is used for the above-mentioned patterning, for example.

Then, the second insulation layer SI (see FIG. 17) is formed using a CVD device. Next, the glass substrate SUB is taken out from the CVD device, a resist film RE is formed on the glass substrate SUB by coating (see FIG. 18) and, thereafter, a resist pattern is formed by photolithography (see FIG. 19). On the other hand, the contact holes CH1, CH2 which are brought into contact with the semiconductor films PS and the contact holes CH3 which are brought into contact with the line-use electrodes CM respectively are formed by performing wet etching one time using hydrofluoric acid or the like, for example (see FIG. 20). Then, the conductive layer is formed and is etched by photolithography such that the contact holes CH1, CH2, CH3 are filled with the conductive layer, and lines are formed so as to cover areas around the contact holes CH1, CH2, CH3 (see FIG. 21), and the protective layer PI is formed over the conductive layer and lines by a CVD device (see FIG. 15). Further, transparent electrodes such as pixel electrodes are formed over the protective layer PI thus manufacturing a conventional array substrate and a conventional liquid crystal display device.

The above-mentioned related art is disclosed in JP-A-11-101990, for example.

### SUMMARY OF THE INVENTION

In the above-mentioned manufacturing method of the conventional display device, however, after the second insulation layer SI is formed on the insulation substrate using a CVD device and before the protective layer PI is formed using the CVD device, it is necessary to form the contact holes CH1, CH2 and CH3 and lines outside the CVD device. Accordingly, the number of times that the insulation substrate is put into the CVD device and is taken out from the CVD device is increased thus eventually making the whole manufacturing steps cumbersome.

The invention has been made in view of such circumstances, and it is an object of the invention to provide a manufacturing method of a display device which can simplify manufacturing steps, and a display device manufactured by such a manufacturing method.

To simply explain the summary of typical inventions among the inventions disclosed in this specification, they are as follows.

According to a first aspect of the invention, there is provided a manufacturing method of a display device which includes the steps of : forming a conductive layer which includes first electrode films and second electrode films which are arranged in a spaced-apart manner from the first electrode films on an insulation substrate; forming a first insulation layer on the insulation substrate on which the conductive layer is formed; forming semiconductor films each of which partially overlaps with at least a portion of the first electrode film in plane on the first insulation layer; forming a second insulation layer on the insulation substrate on which the semiconductor films are formed; forming a protective layer on the insulation substrate on which the second insulation layer is formed; forming, on the protective film, a first resist film having a predetermined thickness in first regions each of which overlaps with at least a portion of each semiconductor film in plane, defining second regions where the resist film is not formed in regions each of which partially overlaps with at least a portion of the second electrode film in plane, and forming second resist films each having a thickness larger than a thickness of the first resist film in regions other than the first regions and the second regions; removing at least a portion of the protective layer, the first insulation layer and the second insulation layer below the second region by etching; removing the first resist films by asking; forming first holes each of which reaches the semiconductor film by exposing the semiconductor film below the first region by etching, and forming second holes each of which reaches the second electrode film below the second region; removing the second resist film; and forming lines which are electrically connected to the semiconductor films via the first holes and lines which are electrically connected to the second electrode films via the second holes.

In one mode of the above-mentioned manufacturing method of a display device, two first regions may be formed in a spaced-apart manner from each other in a region which overlaps with the semiconductor film.

In one mode of the above-mentioned manufacturing method of a display device, the first electrode film may constitute a thin film transistor together with the semiconductor film.

In one mode of the above-mentioned manufacturing method of a display device, the protective layer may contain silicon nitride.

In one mode of the above-mentioned manufacturing method of a display device, the first insulation layer may contain silicon oxide.

In one mode of the above-mentioned manufacturing method of a display device, the second electrode film below the second region may be exposed in the step of removing at least the portion of the protective layer, the first insulation layer and the second insulation layer.

In one mode of the above-mentioned manufacturing method of a display device, the second electrode film below the second region may not be exposed in the step of removing at least the portion of the protective layer, the first insulation layer and the second insulation layer.

In one mode of the above-mentioned manufacturing method of a display device, the first electrode film and the second electrode film may be made of the same material.

In one mode of the above-mentioned manufacturing method of a display device, the first electrode film and the second electrode film may be made of any one selected from a group consisting of Mo, W and an MoW alloy.

According to a second aspect of the invention, there is provided a display device which includes: an insulation substrate; a first conductive layer which is formed on the insulation substrate and from which first electrode films and second electrode films which are formed in a spaced-apart manner from the first electrode films are formed; a first insulation layer which is formed on the first conductive layer; semiconductor layers each of which is formed on the first insulation layer and overlaps with at least a portion of the first electrode film in plane; a second insulation layer which is formed on the semiconductor layer; a protective layer which is formed on the second insulation layer; a plurality of first holes which penetrate the protective layer and the second insulation layer and reach the semiconductor film; one or a plurality of second holes which penetrate the protective layer, the second insulation layer and the first insulation layer and reach the second electrode film; and lines which are electrically connected to the semiconductor films via the first holes and lines which are electrically connected to the second electrode films via the second holes, wherein the second hole has a stepped portion in the inside thereof.

In one mode of the above-mentioned display device, the stepped portion may be formed on the second insulation layer.

In one mode of the above-mentioned display device, the first electrode film and the second electrode film may be made of the same material.

In one mode of the above-mentioned display device, the first electrode film and the second electrode film may be made of any one selected from a group consisting of Mo, W and an MoW alloy.

According to the invention, it is possible to provide a manufacturing method of a display device which can simplify manufacturing steps of a display device by reducing the number of times that the insulation substrate is put into a CVD device and is taken out from the CVD device in the manufacturing steps and a display device which is manufactured by the manufacturing method.

### BRIEF DESCRIPTION OF THE DRAWINGS

FIG. 1 is a view showing an equivalent circuit of a portion of a display region on an array substrate which constitutes an IPS-type liquid crystal display device;

FIG. 2 is an enlarged plan view showing one pixel region on the array substrate according to an embodiment of the invention;

FIG. 3 is a view showing a cross section taken along a line in FIG. 2 and a cross section of contact holes present outside a pixel region;

FIG. 4 is a view for explaining a manufacturing step of the array substrate according to a first embodiment;

FIG. 5 is a view for explaining a manufacturing step of the array substrate according to the first embodiment;

FIG. 6 is a view for explaining a manufacturing step of the array substrate according to the first embodiment;

FIG. 7 is a view for explaining a manufacturing step of the array substrate according to the first embodiment;

FIG. 8 is a view for explaining a manufacturing step of the array substrate according to the first embodiment;

FIG. 9 is a view for explaining a manufacturing step of the array substrate according to the first embodiment;

FIG. 10 is a view for explaining a manufacturing step of the array substrate according to the first embodiment;

FIG. 11 is a view for explaining a manufacturing step of the array substrate according to a second embodiment;

FIG. 12 is a view for explaining a manufacturing step of the array substrate according to the second embodiment;

FIG. 13 is a view for explaining a manufacturing step of the array substrate according to the second embodiment;

FIG. 14 is a view for explaining a manufacturing step of the array substrate according to the second embodiment;

FIG. 15 is a view showing a cross section of a thin film transistor and contact holes formed on an array substrate of a conventional liquid crystal display device;

FIG. 16 is a view for explaining a manufacturing step of a conventional array substrate;

FIG. 17 is a view for explaining a manufacturing step of the conventional array substrate;

FIG. 18 is a view for explaining a manufacturing step of the conventional array substrate;

FIG. 19 is a view for explaining a manufacturing step of the conventional array substrate;

FIG. 20 is a view for explaining a manufacturing step of the conventional array substrate;

FIG. 21 is a view for explaining a manufacturing step of the conventional array substrate;

FIG. 22 is a view showing one example of an equivalent circuit of an array substrate which constitutes a VA-method or TN-method liquid crystal display device; and

FIG. 23 is an enlarged plan view showing one example of a pixel region of an array substrate of the display device adopting the VA method or the TN method.

### DESCRIPTION OF THE PREFERRED EMBODIMENTS

Hereinafter, embodiments of the invention are explained in detail in conjunction with drawings. The embodiments explained hereinafter describe examples of a case where the invention is applied to an IPS (In-Plane-Switching) -type liquid crystal display device.

### First Embodiment

A display device according to this embodiment is a liquid crystal display device, and includes an array substrate, a filter substrate which faces the array substrate in an opposed manner and forms color filters thereon, a liquid crystal material which is sealed in a region sandwiched between both substrates, and a driver IC which is mounted on the array substrate. Both the array substrate and the filter substrate are formed by applying various forming to an insulation substrate such as a glass substrate.

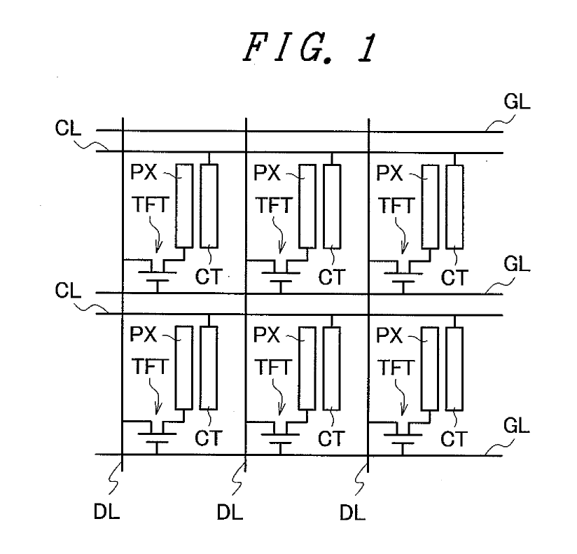

FIG. 1 is a view showing an equivalent circuit of a portion of a display region on an array substrate of the above-mentioned liquid crystal display device. On the array substrate, a large number of gate signal lines GL which extend in the lateral direction and are arranged parallel to each other, and a large number of video signal lines DL which extend in the longitudinal direction and are arranged parallel to each other are formed. Further, a display region is defined in a matrix array by these gate signal lines GL and the video signal lines DL, and each defined region forms one pixel region. Further, a common signal line CL extends in the lateral direction corresponding to each gate signal line GL.

At a corner portion of each pixel region which is defined by the gate signal lines GL and the video signal lines DL, a thin film transistor TFT having the MIS (Metal-Insulator-Semiconductor) structure is formed. A gate electrode GM of the thin film transistor TFT is connected to the gate signal line GL, and a drain electrode DT is connected to the video signal line DL. Further, a pixel electrode PX and a common electrode CT which form a pair are formed in each pixel region, the pixel electrode PX is connected to a source electrode ST of the thin film transistor TFT, and the common electrode CT is connected to the common signal line CL.

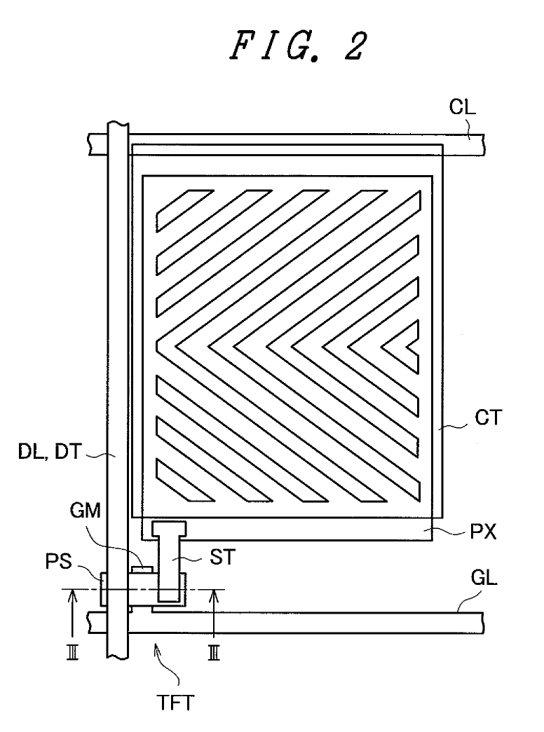

FIG. 2 is a plan view showing one pixel region on the array substrate in an enlarged manner. As shown in FIG. 2, the thin film transistor TFT is arranged at a position where the gate signal line GL and the video signal line DL intersect with each other. The thin film transistor TFT includes a semiconductor film PS. The semiconductor film PS according to this embodiment is positioned above the gate electrode GM which is connected to the gate signal line GL and below the drain electrode DT which is connected to the video signal line DL and the source electrode ST which is connected to the pixel electrode PX. Further, the semiconductor film PS is connected to the drain electrode DT and the source electrode ST. In the example explained in conjunction with FIG. 2, the drain electrode DT forms a portion of the video signal line DL.

In the above-mentioned circuit constitution, a common voltage is applied to the common electrodes CT of the respective pixels via the common signal line CL and a gate voltage is applied to the gate signal line GL so as to select a pixel row. Further, by supplying a video signal to each video signal line DL at such selection timing, a video signal voltage is applied to the pixel electrodes PX of the respective pixels. Due to such an operation, a lateral electric field having intensity corresponding to the video signal voltage is generated between the pixel electrode PX and the common electrode CT, and the alignment direction of liquid crystal molecules is determined corresponding to the intensity of the lateral electric field.

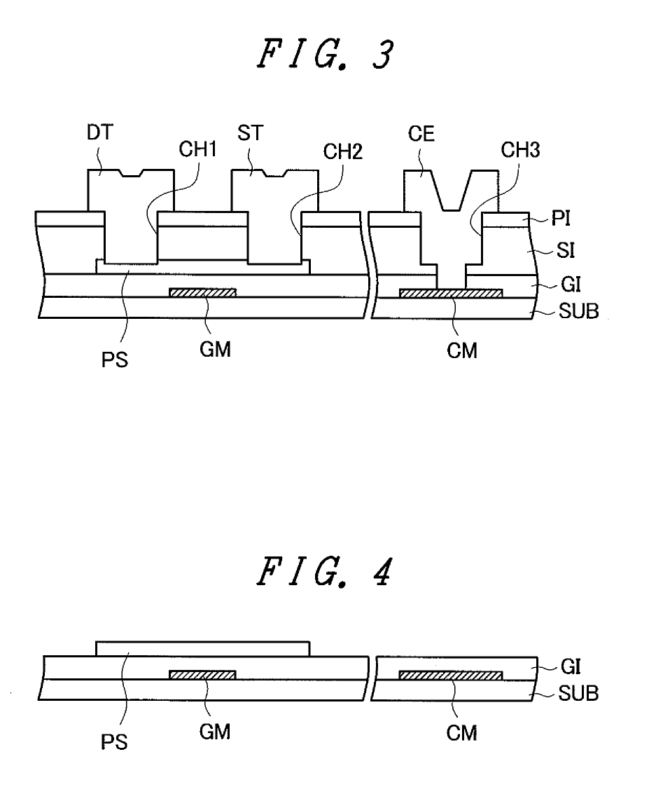

FIG. 3 shows a cross section taken along a line in FIG. 2 and a cross section of a contact hole CH3 which is formed outside the pixel region. To explain the array substrate which includes the thin film transistors TFT and the contact holes CH3 formed outside the pixel regions specifically, the array substrate has the following constitution. That is, on a glass substrate SUB which constitutes an insulation substrate, a conductive layer, a first insulation layer GI formed on the conductive layer, a semiconductor layer formed on the first insulation layer, a second insulation layer SI formed on the semiconductor layer, and a protective layer PI formed on the second insulation layer SI are stacked. The conductive layer is formed of the gate electrodes GM and line-use electrodes CM which are provided in a spaced-apart manner from the gate electrodes GM. The semiconductor layer is formed of the semiconductor films PS arranged above the gate electrodes GM. Further, in the array substrate, a plurality of contact holes CH1, CH2 which penetrate the protective layer PI and the second insulation layer SI and reach the semiconductor film PS and the contact hole CH3 which penetrates the protective layer PI, the second insulation layer SI and the first insulation layer GI and reaches a line-use electrode CM are formed. Still further, in the array substrate, the drain electrode DT and the source electrode ST which constitute lines electrically connected to the semiconductor film PS via the contact holes CH1 CH2 and a contact line CE which constitutes a line electrically connected to the line-use electrode CM via the contact hole CH3 are formed. Differently from the related art, a contact line CE is not present between the second insulation layer SI and the protective layer PI.

The gate electrode GM and the line-use electrode CM are formed of a single layer made of molybdenum, tungsten or a molybdenum-tungsten (MoW) alloy, for example. The first insulation layer GI and the second insulation layer SI are made of silicon oxide. The protective layer PT is made of silicon nitride, and protects the silicon oxide layer which is easily affected by moisture or the like from the outside. Silicon oxide exhibits lower conductivity compared to silicon nitride. The drain electrode DT, the source electrode ST and the contact line CE adopt the structure where an Al alloy such as AlSi is sandwiched between MoW or Ti, for example.

The gate electrode GM and the semiconductor film PS constitute the thin film transistor TFT. In this embodiment, the semiconductor film PS is made of low-temperature poly-silicon. To impart characteristics necessary for a transistor, for example, impurities such as phosphorus are implanted into LDD regions, an n+ region and the like of the semiconductor film PS at various concentrations.

Here, a stepped portion is formed inside the contact hole CH3. Compared to a conventional line which is formed in a contact hole, a contact line CE which is a layer made of an Al alloy such as AlSi, or MoW, Ti or the like and is formed on an inner side or a peripheral portion of the contact hole CH3 increases a size or a diameter thereof above the stepped portion. Accordingly, the electric resistance of the contact line CE can be decreased.

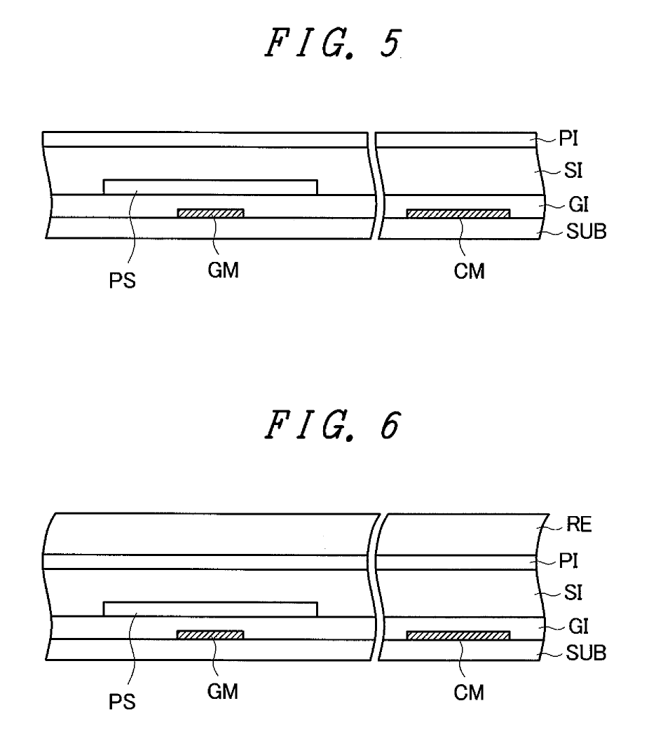

A method of manufacturing the array substrate having the above-mentioned structure is explained hereinafter. Firstly, a film made of MoW or the like is formed on the glass substrate SUB, and the gate electrodes GM and the line-use electrode CM are formed by patterning using photolithography. Then, a silicon oxide film is formed by a CVD device thus forming the first insulation layer GI. Subsequently, a semiconductor layer containing a material such as low-temperature poly-silicon (LTPS) is formed as a film and, thereafter, this layer is patterned using photolithography while adding impurities necessary for an operation of a transistor to the layer thus forming the semiconductor films PS. FIG. 4 shows the array substrate at this stage. Then, a silicon oxide film and a silicon nitride film are continuously formed by a CVD device thus bringing about a state shown in FIG. 5 where the second insulation layer SI and the protective layer PI are respectively formed on the glass substrate SUB.

Steps for forming the contact holes CH1, CH2, CH3 shown in FIG. 3 are explained hereinafter. A photo resist is applied by coating to the glass substrate SUB on which the layers up to the protective layer PI are formed. FIG. 6 shows the array substrate at this stage. Next, a resist film RE is formed on the glass substrate SUB by patterning using half -tone exposure.

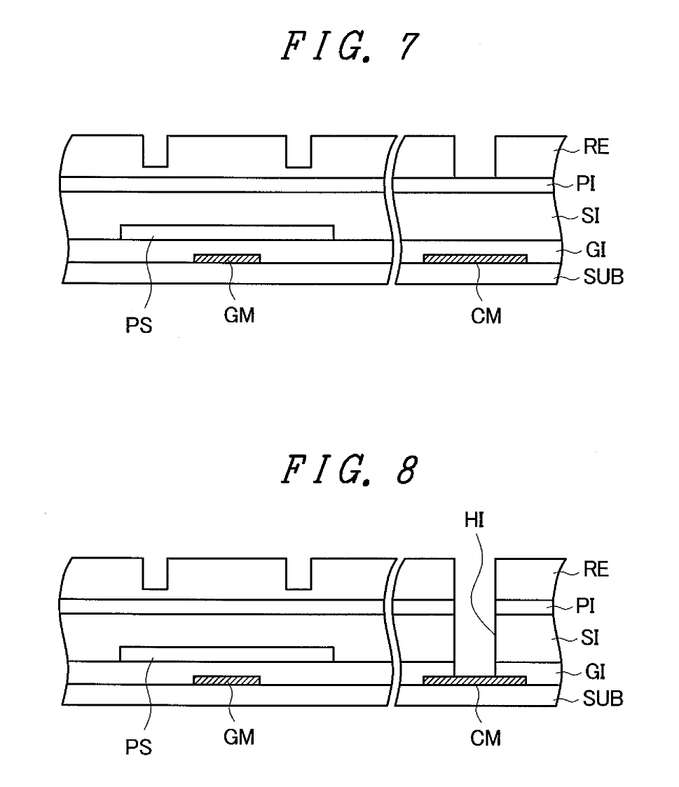

The resist film RE includes regions for forming the contact holes CH3 where the region has no film thickness, that is, opening portions where the resist film RE is not present, regions for forming the contact holes CH1, CH2 where a film thickness is small due to half-tone exposure, and other regions where the half-tone exposure is not used so that a film thickness is large compared to other regions. FIG. 7 shows the array substrate at this stage. Here, a size of the opening portions of the resist film RE or a size of the region where the film thickness of the resist film is small is preliminarily determined by estimating the planar expansion of the film which takes place in an ashing step performed later.

Next, the first etching step is performed. To be more specific, in this step, for example, by performing dry etching using a fluorocarbon gas or a sulfur hexafluoride gas, holes HI which penetrate the protective layer PI, the second insulation layer SI and the first insulation layer GI and reach the line-use electrodes CM are formed in the regions for forming the contact holes CH3. FIG. 8 shows the array substrate at this stage. The line-use electrode CM is exposed on a bottom of the hole HI due to such a step. On the other hand, the regions for forming the contact holes CH1, CH2 are covered with the resist film RE which constitutes a mask and hence, no holes are formed in the protective layer PI in this step.

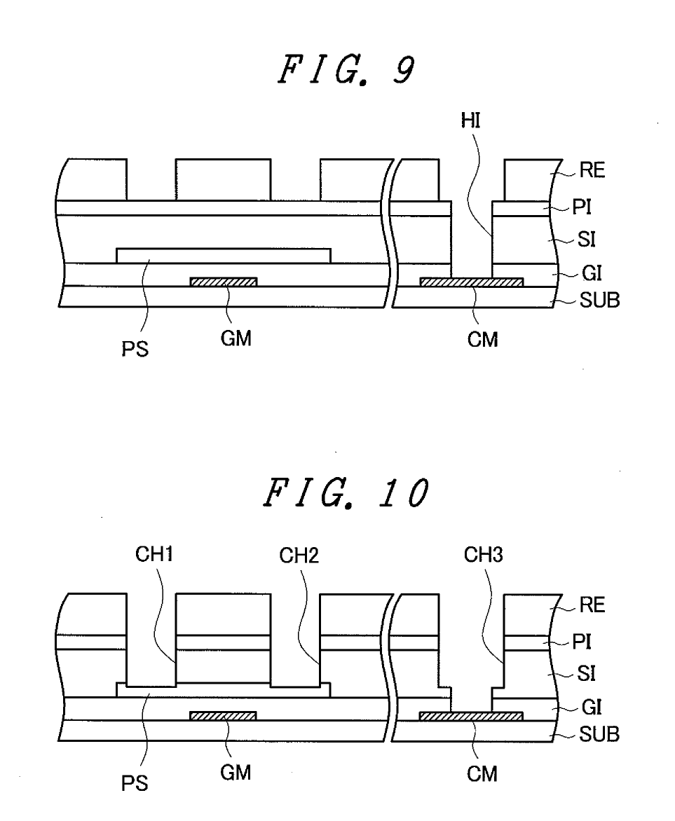

Then, the resist film RE in the regions for forming the contact holes CH1, CH2 is removed by ashing. FIG. 9 shows the array substrate at this stage. Due to such ashing, not only a thickness of the resist film RE is decreased but also a size of the opening portion is increased. The resist film RE above the hole HI is also retracted so that an upper surface of the protective layer PI is exposed in the opening portion of the resist film RE.

Next, the second etching step is performed. To be more specific, by performing dry-etching using a fluorocarbon gas, a sulfur hexafluoride gas or the like, for example, a hole is formed in the regions for forming the contact holes CH1, CH2 and the formation of the hole is adjusted to prevent further etching at a point of time that the hole reaches the semiconductor film PS. FIG. 10 shows the array substrate at this stage. Due to such steps, the contact holes CH1, CH2, CH3 are formed. A portion of the contact hole CH3 includes a stepped portion therein, wherein the stepped portion is formed by etching the portion where the resist film RE is retracted by ashing.

After performing the second etching step, the resist film RE is removed, and an Al alloy such as AlSi, or MoW, Ti or the like is stacked. This embodiment adopts the three-layered structure where an MoW layer, an AlSi layer and an MoW layer are stacked in order. Due to such stacked structure, the above-mentioned metal layers are also formed inside the contact holes CH1, CH2, CH3. Then, patterning is performed so as to form lines which are connected with these contact holes. Due to such a constitution, the drain electrodes DT, the source electrodes ST and the contact lines CE which are lines shown in FIG. 3 and video signal lines DL and the like which are not shown in the drawing are formed. Thereafter, the common electrodes CT, the pixel electrodes PX and the like are formed on the glass substrate SUB thus completing the array substrate.

In the above-mentioned manufacturing method, differently from the related art, the film which constitutes the second insulation layer SI and contains silicon oxide and the film which constitutes the protective layer PI and contains silicon nitride are continuously formed. That is, the second insulation layer SI and the protective layer PI can be formed without putting the glass substrate SUB into the CVD device and taking out the glass substrate SUB from the CVD device and hence, the number of times that the glass substrate SUB is put into the CVD device and is taken out from the CVD device is decreased compared to the conventional manufacturing method. Accordingly, steps including an operation for putting the glass substrate SUB into the CVD device and taking out the glass substrate SUB from the CVD device, re-heating and the like can be omitted. As a result, the whole steps can be simplified leading to the reduction of a manufacturing cost.

Further, in this embodiment, in forming the contact holes CH1, CH2, CH3, to etch both silicon nitride and silicon oxide at a time, dry etching is performed using a fluorocarbon gas or a sulfur hexafluoride gas. This etching technique cannot ensure a selection ratio between the protective layer PI and the second insulation layer SI as well as between the semiconductor film PS and the first insulation layer GI and hence, it is difficult to form the contact holes CH1, CH2 which reach an upper surface of the semiconductor film PS and the contact hole CH3 which reaches the line-use electrode CM at a time. For example, when etching is performed such that the contact holes reach the line-use electrode, the contact holes penetrate the semiconductor film PS. As another method, the contact holes CH1, CH2 and the contact hole CH3 may be formed by etching separately using different photolithography techniques. However, the number of times of photolithography is increased so that the steps are not simplified as a whole. However, by performing the above-mentioned steps consisting of first etching, ashing and second etching, it is possible to form the holes which reach both the semiconductor film PS and the line-use electrode CM without increasing the number of times of photolithography. Accordingly, the steps can be simplified as a whole.

### Second Embodiment

A display device according to this embodiment is a liquid crystal display device, and the constitution of the liquid crystal display device including an array substrate and the like is substantially equal to the constitution of the liquid crystal display device of the first embodiment. Further, the array substrate per se has the same structure as the array substrate of the first embodiment. Further, the difference in manufacturing steps between this embodiment and the first embodiment lies in the steps for forming the contact holes CH1 CH2, CH3. The second embodiment is explained hereinafter by mainly focusing on the constitution which makes this embodiment different from the first embodiment.

In forming the contact holes CH1, CH2, CH3, a photo resist is applied by coating to a glass substrate SUB on which a second insulation layer SI and a protective layer PI are formed as shown in FIG. 5. Next, using half-tone exposure, a resist film RE is formed by patterning. A series of steps including the formation of the resist film RE is substantially equal to a series of corresponding steps of the first embodiment (see FIG. 6 and FIG. 7).

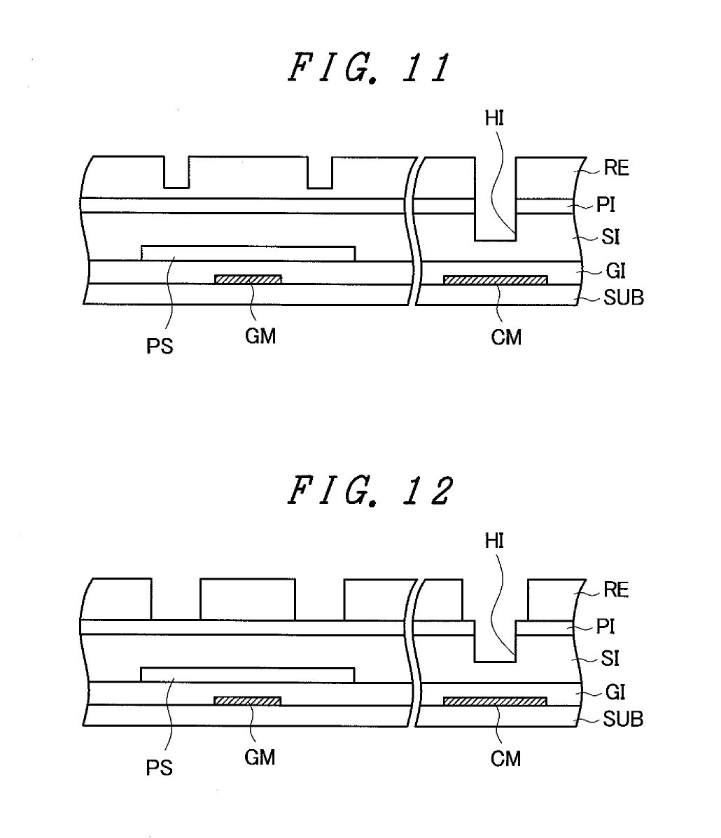

Next, the first etching step is performed. To be more specific, for example, by performing dry etching using a fluorocarbon gas or a sulfur hexafluoride gas, holes HI which penetrate the protective layer PI and reach a preset depth are formed in a region for forming the contact holes CH3. FIG. 11 shows the array substrate at this stage. A depth of the hole HI is adjusted such that the hole HI does not reach a line-use electrode CM in this step, and the line-use electrode CM is exposed in the second etching step. It is ideal that the depth of the hole HI is adjusted such that the hole HI reaches the line-use electrode CM immediately before the second etching is finished. On the other hand, regions for forming the contact holes CH1, CH2 are covered with the resist film RE which constitutes a mask and hence, holes are not formed in a protective layer PI in this step.

Then, the resist film RE in the regions for forming the contact holes CH1, CH2 is removed by ashing. FIG. 12 shows the array substrate at this stage. The resist film RE above the hole HI is also retracted so that an upper surface of the protective layer PI is exposed in the opening portion of the resist film RE.

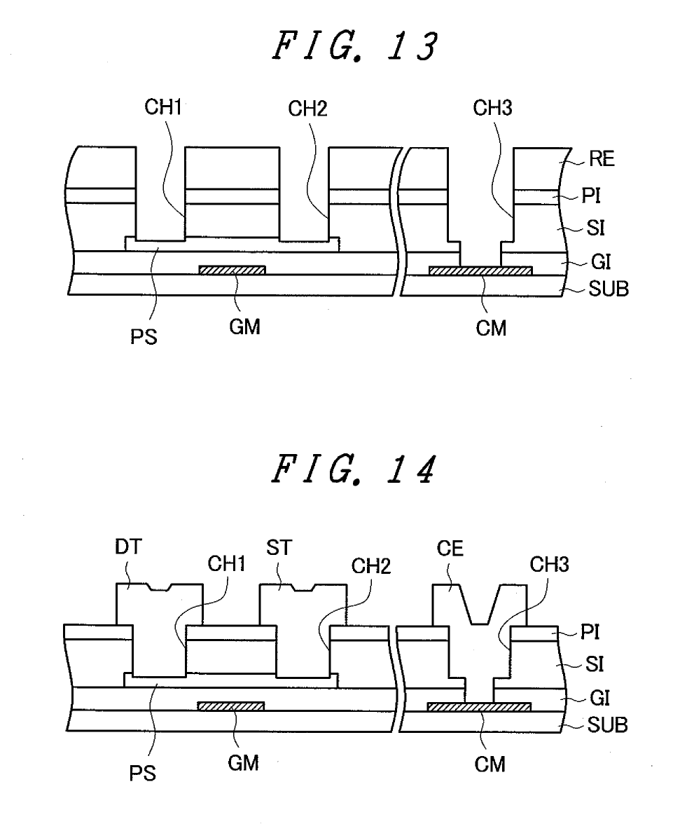

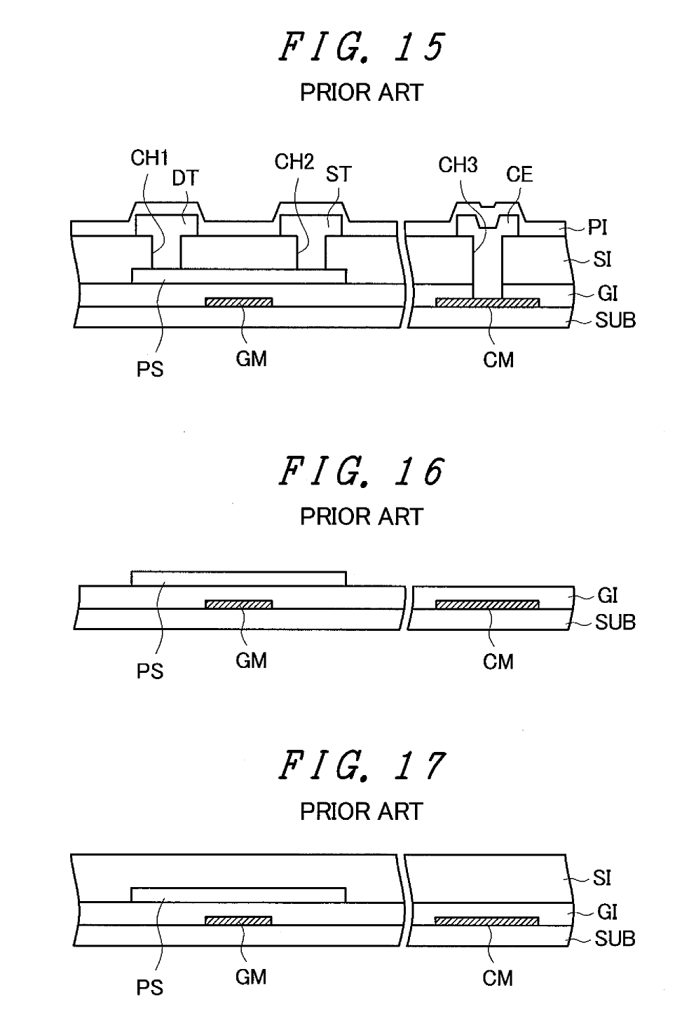

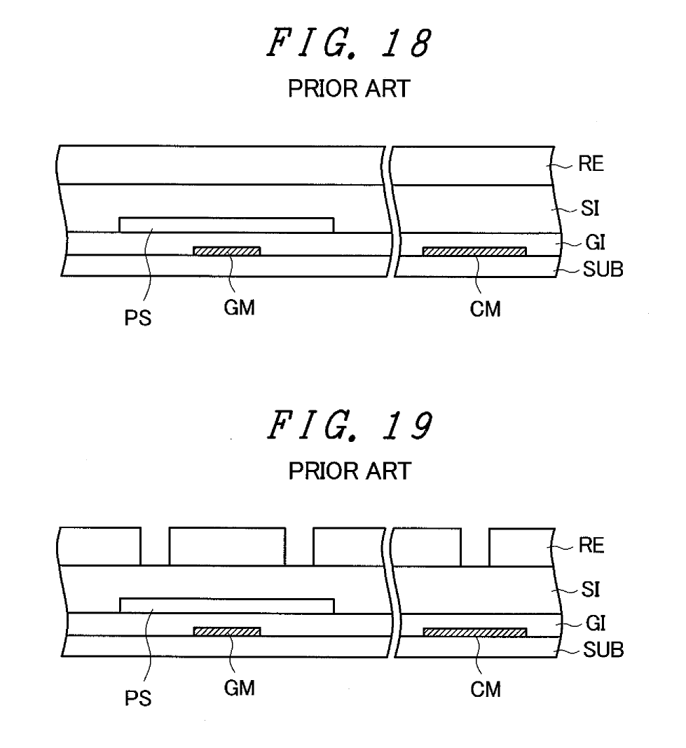

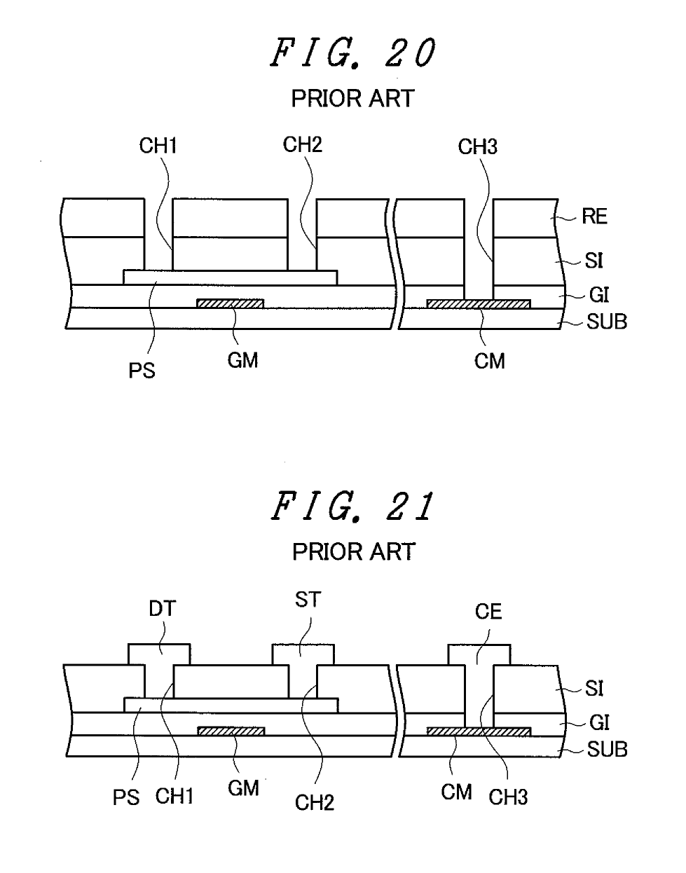

Next, the second etching step is performed. To be more specific, by performing dry etching using a fluorocarbon gas, a sulfur hexafluoride gas or the like, for example, a hole is formed in the regions for forming the contact holes CH1, CH2, and the formation of the hole is adjusted to prevent further etching at a point of time that the hole reaches the semiconductor film PS. FIG. 13 shows the array substrate at this stage. Due to such steps, the contact holes CH1, CH2, CH3 are formed. A portion of the contact hole CH3 includes a stepped portion therein, wherein the stepped portion is formed by etching the portion where the resist film RE is retracted by ashing and the hole HI.

After performing the second etching step, the resist film RE is removed, and an Al alloy such as AlSi, or MoW, Ti or the like is stacked. In the same manner as the first embodiment, this embodiment adopts the three-layered structure where an MoW layer, an AlSi layer and an MoW layer are stacked in order. Due to such stacked structure, the above-mentioned metal layers are also formed inside the contact holes CH1, CH2, CH3. Then, patterning is performed so as to form lines which are connected with these contact holes. Due to such a constitution, the drain electrodes DT, the source electrodes ST and the contact lines CE which are lines shown in FIG. 14 and video signal lines DL and the like which are not shown in the drawing are formed. Thereafter, the common electrodes CT, the pixel electrodes PX and the like are formed on the glass substrate SUB thus completing the array substrate.

The manufacturing method of a liquid crystal display device according to the second embodiment can reduce a time during which the line-use electrode CM is exposed to the outside in the ashing step and the second etching step. Accordingly, a time during which the line-use electrode CM is brought into contact with a gas for dry etching, for example, can be reduced thus suppressing damages such as oxidation of the line-use electrode CM eventually.

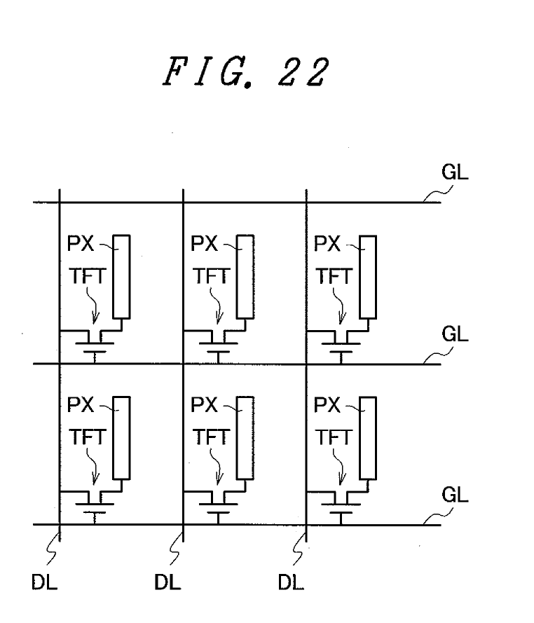

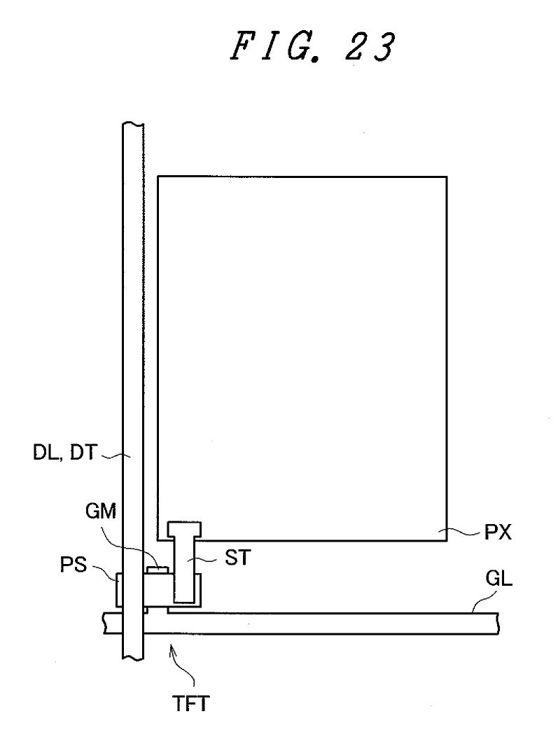

The invention has been explained heretofore with respect to the case where an IPS method is used as a driving method of liquid crystal in the liquid crystal display device of the embodiments. However, the invention may adopt other liquid-crystal driving method such as a VA (Vertically aligned) method or a TN (Twisted Nematic) method, for example. FIG. 22 is a view showing one example of an equivalent circuit of an array substrate which constitutes a VA-method or TN-method display device, and FIG. 23 is an enlarged plan view showing one example of a pixel region of the array substrate of the display device adopting the VA method or the TN method. In case of the VA method or the TN method display device, in place of forming the common electrodes CT and the common signal lines CL on the array substrate, a common electrode is formed on a counter substrate (or a color filter substrate) not shown in the drawing which faces the array substrate in an opposed manner. Also in the liquid crystal display device adopting these methods, the structure of the thin film transistor TFT and the contact hole CH3 which constitute essential parts excluding the common electrodes CT is substantially equal to the corresponding structure of the first embodiment or the second embodiment.

Although the embodiments of the invention have been explained using the liquid crystal display device as the display device, the invention is not limited to the liquid crystal display device. It is needless to say that the invention is also applicable to other display devices such as an organic EL (Electro Luminescence) element, for example, provided that the display device includes the similar stacked structure including an insulation layer and a conductive layer.

What is claimed is:

1. A manufacturing method of a display device comprising the steps of:
forming a conductive layer which includes first electrode films and second electrode films which are arranged in a spaced-apart manner from the first electrode films on an insulation substrate;
forming a first insulation layer on the insulation substrate on which the conductive layer is formed;
forming semiconductor films each of which partially overlaps with at least a portion of the first electrode film in plane on the first insulation layer;
forming a second insulation layer on the insulation substrate on which the semiconductor films are formed;
forming a protective layer on the insulation substrate on which the second insulation layer is formed;
forming, on the protective film, a first resist film having a predetermined thickness in first regions each of which overlaps with at least a portion of each semiconductor film in plane, defining second regions where the resist film is not formed in regions each of which partially overlaps with at least a portion of the second electrode film in plane, and forming second resist films each having a thickness larger than a thickness of the first resist film in regions other than the first regions and the second regions;
removing at least a portion of the protective layer, the first insulation layer and the second insulation layer below the second region by etching;
removing the first resist films by ashing;
forming first holes each of which reaches the semiconductor film by exposing the semiconductor film below the first region by etching, and forming second holes each of which reaches the second electrode film below the second region;
removing the second resist film; and
forming lines which are electrically connected to the semiconductor films via the first holes and lines which are electrically connected to the second electrode films via the second holes.

2. A manufacturing method of a display device according to claim 1, wherein two first regions are formed in a spaced-apart manner from each other in a region which overlaps with the semiconductor film.

3. A manufacturing method of a display device according to claim 1, wherein the first electrode film constitutes a thin film transistor together with the semiconductor film.

4. A manufacturing method of a display device according to claim 1, wherein the protective layer contains silicon nitride.

5. A manufacturing method of a display device according to claim 1, wherein the first insulation layer contains silicon oxide.

6. A manufacturing method of a display device according to claim 1, wherein the second electrode film below the second region is exposed in the step of removing at least the portion of the protective layer, the first insulation layer and the second insulation layer.

7. A manufacturing method of a display device according to claim 1, wherein the second electrode film below the second region is not exposed in the step of removing at least the portion of the protective layer, the first insulation layer and the second insulation layer.

8. A manufacturing method of a display device according to claim 1, wherein the first electrode film and the second electrode film are made of the same material.

9. A manufacturing method of a display device according to claim 8, wherein the first electrode film and the second electrode film are made of any one selected from a group consisting of Mo, W and an MoW alloy.

10. A display device comprising:
an insulation substrate;
a first conductive layer which is formed on the insulation substrate and from which first electrode films and second electrode films which are formed in a spaced-apart manner from the first electrode films are formed;
a first insulation layer which is formed on the first conductive layer;
semiconductor layers each of which is formed on the first insulation layer and overlaps with at least a portion of the first electrode film in plane;
a second insulation layer which is formed on the semiconductor layer;
a protective layer which is formed on the second insulation layer;
a plurality of first holes which penetrate the protective layer and the second insulation layer and reach the semiconductor film;
one or a plurality of second holes which penetrate the protective layer, the second insulation layer and the first insulation layer and reach the second electrode film; and
lines which are electrically connected to the semiconductor films via the first holes and lines which are electrically connected to the second electrode films via the second holes, wherein
the second hole has a stepped portion in an inside thereof.

11. A display device according to claim 10, wherein the stepped portion is formed on the second insulation layer.

12. A display device according to claim 10, wherein the first electrode film and the second electrode film are made of the same material.

13. A display device according to claim 12, wherein the first electrode film and the second electrode film are made of any one selected from a group consisting of Mo, W and an MoW alloy.
